(19) United States
(12) Patent Application Publication
(10) Pub. No.: US 2010/0181500 A1
(43) Pub. Date: Jul. 22, 2010

(54) METHOD AND SYSTEM FOR LOW TEMPERATURE ION IMPLANTATION

(75) Inventors: Chun-Lin Chang, Jhubei City (TW); Zin-Chang Wei, Hsin-Chu City (TW); Hsin-Hsien Wu, Hsinchu City (TW)

Correspondence Address: DUANE MORRIS LLP (TSMC);IP DEPARTMENT, 30 SOUTH 17TH STREET, PHILADELPHIA, PA, 19103-4196, US

(73) Assignee: Taiwan Semiconductor Manufacturing Co., Ltd., Hsin-Chu (TW)

(21) Appl. No.: 12/355,443

(22) Filed: Jan. 16, 2009

(51) Int. Cl. H01J 37/08

(52) U.S. Cl. 250/492.21

(57) ABSTRACT

A method comprises pre-cooling a first semiconductor wafer outside of a process chamber, from a temperature at or above 15° C. to a temperature below 5° C. The pre-cooled first wafer is placed inside the process chamber after performing the pre-cooling step. A low-temperature ion implantation is performed on the first wafer after placing the first wafer.

### FIELD OF THE INVENTION

The present disclosure relates to semiconductor integrated circuit manufacturing.

### BACKGROUND

Extrinsic semiconductors rely on dopants to provide a desired density of charge carriers. Two major steps are involved: dopant implantation and dopant activation. In conventional CMOS manufacturing, an ion beam implants dopants into the wafer. Ion implantation causes damage to the crystal structure of the target which is often unwanted. For example, it has been determined that ion implantation in silicon conducted at high temperatures results in lattice defects. U.S. Pat. No. 5,087,576 suggests that, when silicon is ion implanted at high temperatures, sufficient energy is imparted to the lattice by the incoming ions to cause individual point defects to arrange themselves in a lower energy configuration. These configurations include planar (stacking faults) and line (disclosure or loops) defects, with line defects forming somewhat more often. These defects are detrimental to the operation of any resulting device formed from that material.

U.S. Pat. No. 5,087,576 describes ion implantation which is conducted when the target is at a rather low temperature, specifically temperatures on the order of the boiling point of liquid nitrogen (77° K., −196° C.). Under such circumstances, the implantation bombardment of ions creates a totally amorphous region in the target crystal, i.e. one in which no specific crystal structure is present. Performing annealing following the low temperature implantation encourages the implanted region—i.e. the layer represented by the depth to which the bombarding ions have penetrated—to recrystallize into a layer which resembles an epitaxial growth portion, giving this technique the name “solid-phase-epitaxy.”

Another result of low temperature implantation (e.g., at −196° C.) is suppression of self-annealing, which may be desirable in some processes.

In some recipes, by implanting dopants into the crystalline material in an ion implantation high vacuum chamber adapted to keep the crystal near −190° C. during the ion implantation step, diffusion of the highly mobile crystalline constituents may be avoided.

FIG. 1 shows a conventional implantation tool 100. The tool 100 has a wafer transfer chamber 102, which maintains the wafers in a sealed vacuum environment. A plurality of loadlocks 104 are connectible to the wafer transfer chamber 102. The loadlocks 104 can vent to atmospheric pressure. The loadlocks 104 are configured to receive wafers 105 from the four-loadport atmosphere-transfer module 114, or other robotic device. The loadlocks 104 are then sealed shut and evacuated to vacuum pressure. The wafers 105 can then be transferred from the loadlocks 104 to the wafer transfer chamber 102 without interrupting the vacuum or process flow in wafer transfer chamber 102. The wafers 105 are transferred from the wafer transfer chamber 102 to the process cooling platen 106 of the process chamber 112. The process cooling platen 106 is cooled by a refrigerant supplied in cooling lines 116 by a first compressor 118, and optionally a second compressor 120, for cooling to lower temperatures. The process chamber 112 has a scan motor 108 that produces and ion beam 110 for the implantation process step.

FIG. 2 is a flow chart of the conventional procedure to implement a low temperature implantation step.

At step 200, the wafer is placed in the loadlock 104. Air is vacuumed out.

At step 202, the wafer is moved into the transfer chamber 102.

At step 204, the wafer 105 is transferred from the wafer transfer chamber 102 to the cooling platen 106 of the process chamber 112. The wafer 105 is cooled on the process cooling platen 106 in the process chamber 112 of the implantation tool 100.

At step 206, after a delay of about 15-20 seconds for cooling, the wafer is ready for implantation in the process chamber 112.

The cooling time on the process cooling platen 106 may be about 15-20 seconds to reach liquid nitrogen (LN2) temperature of about −190° C., which adds 15-20 seconds of idle time to each implantation step. This has a substantial negative impact on the productivity of the implantation tool 100, because its duty cycle is reduced. A typical implantation step lasts about 60 seconds, so the best duty cycle achievable with a 20 second delay is 75%.

### SUMMARY OF THE INVENTION

In some embodiments, a method comprises pre-cooling a first semiconductor wafer outside of a process chamber, from a temperature at or above 15° C. to a temperature below 5° C. The pre-cooled first wafer is placed inside the process chamber after performing the pre-cooling step. A low-temperature ion implantation is performed on the first wafer after placing the first wafer.

In some embodiments, apparatus comprises a wafer transfer chamber coupled to receive a semiconductor wafer from a loadlock. The wafer transfer chamber is configured to pre-cool a first semiconductor wafer from a first temperature to a second temperature, where the first temperature is at least 15° C., the second temperature is greater than or equal to −270° C., and the second temperature is less than or equal to 5° C. A process chamber is configured to receive the pre-cooled wafer from the wafer transfer chamber and to perform an ion implantation step on the wafer at the temperature greater than or equal to −270° C. and less than or equal to 5° C.

In some embodiments, apparatus comprises a loadlock configured to pre-cool a first semiconductor wafer from a first temperature to a second temperature, where the first temperature is at least 15° C., the second temperature is greater than or equal to −270° C., and the second temperature is less than or equal to 5° C. A wafer transfer chamber is coupled to the loadlock to receive the pre-cooled wafer therefrom without exposing the wafer to an ambient atmosphere. A process chamber is configured to receive the pre-cooled wafer from the wafer transfer chamber and to perform an ion implantation step on the wafer at the temperature greater than or equal to −270° C. and less than or equal to 5° C.

### BRIEF DESCRIPTION OF THE DRAWINGS

FIG. 1 is a schematic diagram of a conventional apparatus.

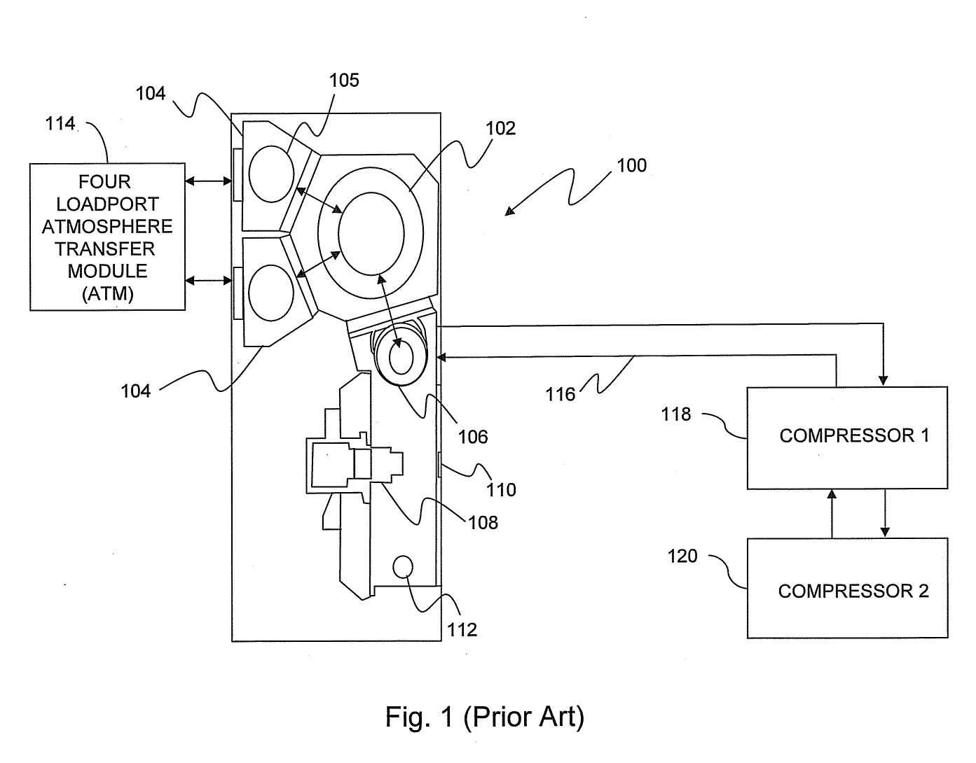

FIG. 2 is a flow chart of a method performed using the apparatus of FIG. 1.

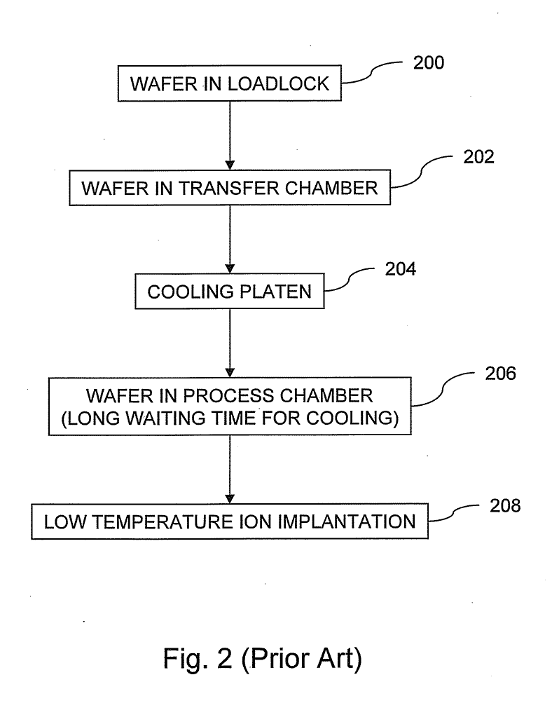

FIG. 3 is a schematic diagram of an exemplary apparatus.

FIG. 4 is a flow chart of a method performed using the apparatus of FIG. 3.

FIG. 5 is a schematic diagram of a variation of the apparatus of FIG. 3.

FIG. 6 is a flow chart of a method performed using the apparatus of FIG. 5.

FIG. 7 is a flow chart of a variation of the method of FIG. 6.

### DETAILED DESCRIPTION

This description of the exemplary embodiments is intended to be read in connection with the accompanying drawings, which are to be considered part of the entire written description. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

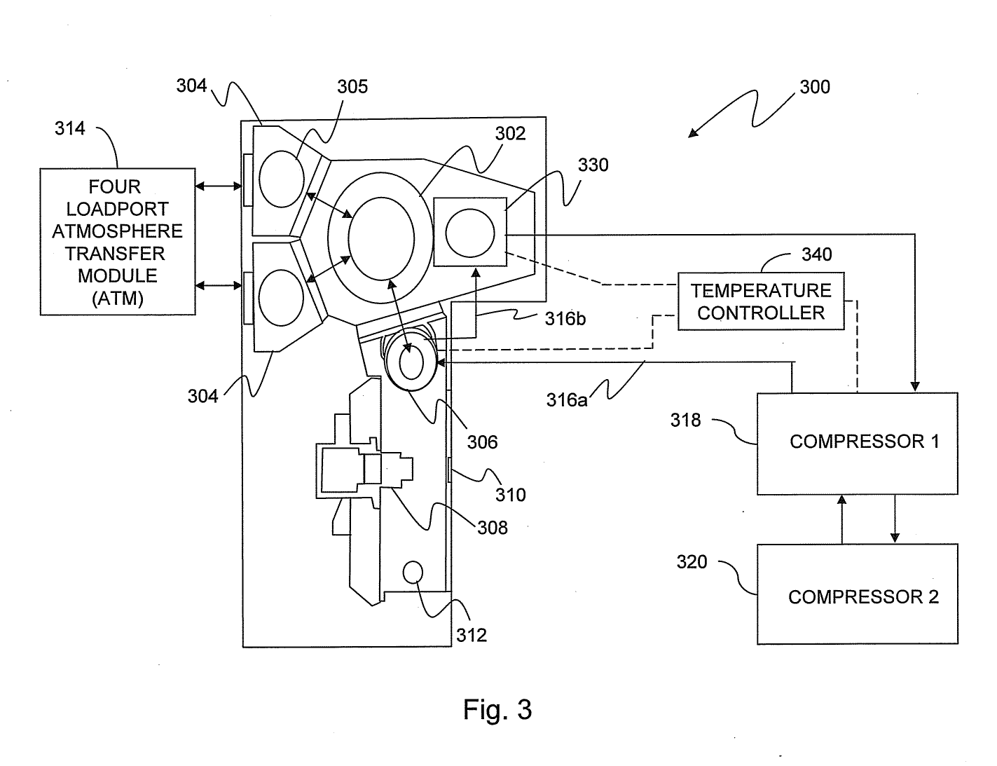

FIG. 3 is a schematic diagram of a first exemplary apparatus 300. The tool 300 has a wafer transfer chamber 302, which maintains the wafers in a sealed vacuum environment. A plurality of loadlocks 304 are connectible to the wafer transfer chamber 302. The loadlocks 304 can vent to atmospheric pressure. The loadlocks 304 are configured to receive wafers 305 from the four-loadport atmosphere-transfer module 314, or other robotic device. The loadlocks 304 are then sealed shut and evacuated to vacuum pressure. The wafers 305 can then be transferred from the loadlocks 304 to the wafer transfer chamber 302 without interrupting the vacuum or process flow in wafer transfer chamber 302.

The wafer transfer chamber 302 is coupled to receive a semiconductor wafer 305 from a loadlock 304 and configured to pre-cool a first semiconductor wafer from a first temperature to a second temperature for implantation. In some embodiments, the first temperature is at least 15° C., the second temperature is greater than or equal to −270° C., and the second temperature is less than or equal to 5° C. In some embodiments, the wafer transfer chamber 302 has a cooling stage 330 inside the transfer chamber. The cooling stage 330 has a surface for holding the wafer 305. A coolant is either circulated through conduits within the wafer stage, or through conduits (e.g., tubing) on the back surface of the cooling stage 330 opposite the wafer 305.

In some embodiments, a common coolant source 318 provides a coolant to the cooling stage 330 of the wafer transfer chamber 302 and to a process cooling platen 306 that holds and cools the wafer 305 within the process chamber 312. For example, the coolant may be a cryogenic fluid, such as a coolant from the group consisting of liquid hydrogen (20 K, −253 C.), liquid helium (3 K, −270 C.), liquid nitrogen (77 K, −196 C.), liquid oxygen (90 K, −183 C.), liquid methane (112 K, −162 C), and liquid nitrous oxide (88 K, −185 C). Thus, the cooling stage 330 and cooling platen 306 can be cooled to a selected one of these temperatures. Alternatively, a refrigerated, non-cryogenic coolant may be used to provide a temperature of about −50 C., 0 C., or 5 C. Depending on the configuration of the cooling stage, and the thermal conductance of the materials therein, the wafer temperature may be from 2 to 10 degrees higher than the temperature of the coolant.

One or more compressors 318, 320 are provided to cool the coolant to the desired temperature. Suitable conduits 316a, 316b transmit the coolant from the compressor to the cooling platen 306 and cooling stage 330. Although FIG. 3 shows the coolant routed first to cooling platen 306 via conduit 316a and then to cooling stage 330 via conduit 316b, in other embodiments, the coolant is routed first to cooling stage 330 and then to cooling platen 306. In other embodiments, the coolant is routed to cooling platen 306 and cooling stage 330 in parallel, and parallel return paths are provided.

In some embodiments, a common temperature controller 340 controls both the temperature of the cooling stage 330 and the temperature of the cooling platen 306. If a single coolant is provided to the cooling stage 330 and cooling platen 306 at a single temperature, then the temperatures of the cooling stage 330 and cooling platen 306 can be modulated by varying the duty cycle of the flow to each.

The temperature controller may employ one of a variety of methods to control the cooling. For example, the coolant delivery may cycle on whenever the temperature of the cooling stage 330 rises above a setpoint, and shut off when the temperature falls below that setpoint. Hysteresis may be added (e.g., by including a Schmitt trigger in the controller) to allow the temperature to vary by a small amount, so that the coolant delivery does not continuously cycle on and off. Essentially, coolant delivery turns on when the temperature rises above a first temperature, and turns off when the temperature falls below a second temperature. For example, using liquid nitrogen (−196 C.) as coolant, the coolant delivery may turn on when the temperature of cooling stage 330 reaches −190 C. and turn off when the temperature reaches −194 C.

The process chamber 312 is configured to receive the pre-cooled wafer from the wafer transfer chamber and to perform an ion implantation step on the wafer at the temperature between −270° C. and 5° C. This can be achieved using any suitably equipped process chamber with a process cooling platen for maintaining the low temperature during the ion implantation. Because the ion beam adds energy to the wafer 305, the wafer 305 is continuously cooled during implantation to maintain the low temperature. Any process chamber that is capable of cooling the wafer to a low temperature for ion implantation may be used for the process of FIG. 3, which delivers the wafer in a pre-cooled state.

The wafers 305 are transferred from the wafer transfer chamber 302 to the process cooling platen 306 of the process chamber 312. The process cooling platen 306 is cooled by a refrigerant supplied in cooling lines 316 by a first compressor 318, and optionally a second compressor 320, for cooling to lower temperatures. The process chamber 312 has a scan motor 308 that produces and ion beam 310 for the implantation process step.

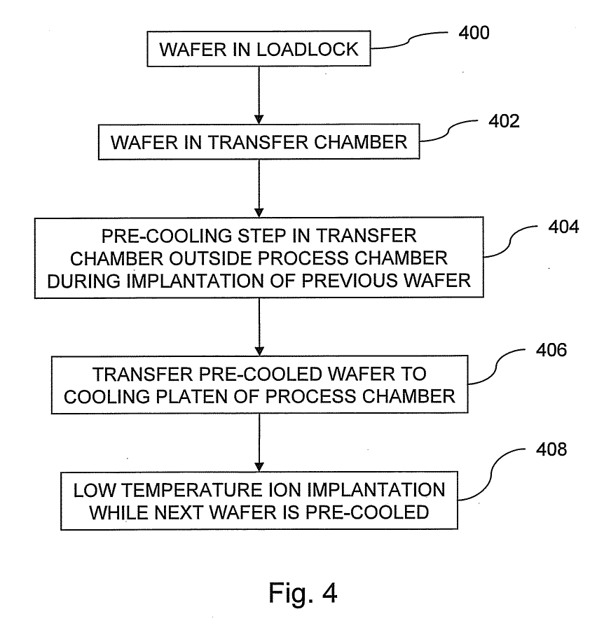

FIG. 4 is a flow chart of a method of using the apparatus 300 of FIG. 3.

At step 400, the wafer 305 is placed in one of the loadlocks 304. A cooling gas may optionally be fed into the loadlock 304, to reduce the temperature of the wafer 305 before transferring the wafer 305 into the wafer transfer chamber 302. The loadlock 304 is sealed and the atmosphere (or optional cooling gas, if used) is vacuumed out of the loadlock.

At step 402, the port between the loadlock 304 and wafer transfer chamber 302 is opened, and the wafer 305 is transferred to the wafer transfer chamber.

At step 404, the wafer 305 is pre-cooled on the cooling stage 330, outside of the process chamber. Preferably, the wafer 305 is pre-cooled to the temperature at which ion implantation is to occur. During the time that the pre-cooling step is performed, a previous wafer is either being transferred into position in the process chamber 312 or on the process cooling platen 306, being subjected to the ion implantation. Thus, two steps are being performed in parallel.

At step 406, the pre-cooled wafer 305 is transferred from the wafer transfer chamber 302 to the cooling platen 406 of the process chamber.

At step 408, the low temperature ion implantation step is performed while the next succeeding wafer is already being pre-cooled in the cooling stage 330. Thus, the apparatus 300 is capable of starting the ion implantation step within a first period of time after the wafer 305 is placed on the process cooling platen 306, where the first period of time is shorter than a second period of time (e.g., 15-20 seconds) within which the process cooling platen is capable of cooling a semiconductor wafer from the temperature at or above 15° C. to the temperature between −270° C. and 5° C. The duty cycle of the process chamber 312 is thus improved. Instead of waiting 15-20 seconds (while a wafer cools) between implantation steps, the only delay between implantation steps is the amount of time used to remove a first wafer 305 from the process cooling platen 306 of the process chamber 312 and to transfer a second wafer to the process cooling platen 306. This time interval is substantially less than the 15-20 second delay of pre-cooling the wafer 305, and may be only a few seconds of less.

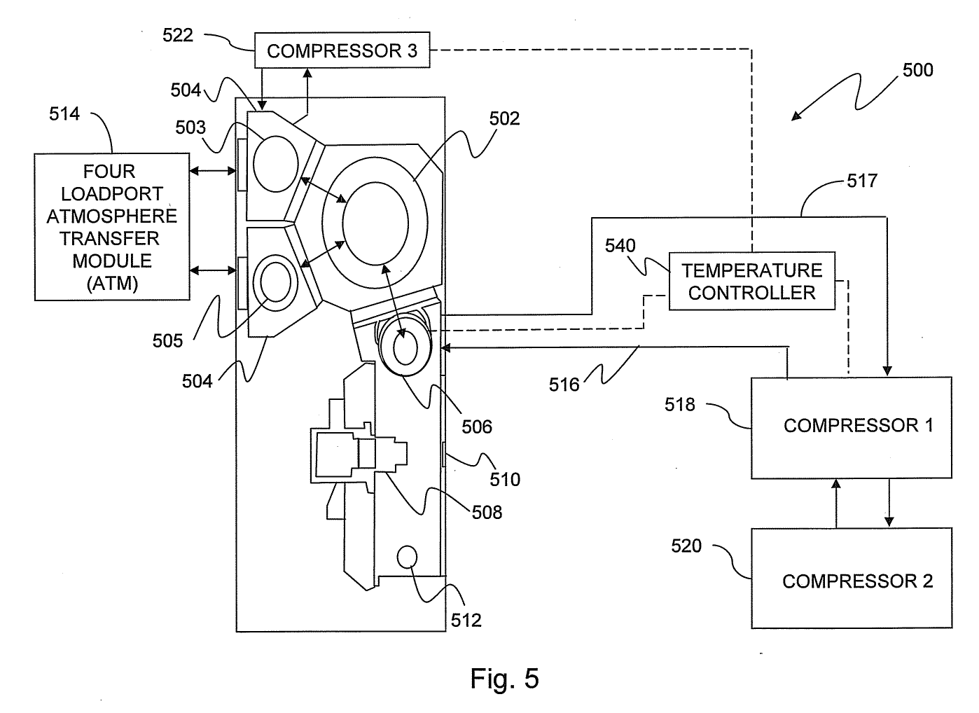

FIG. 5 is a schematic diagram of another apparatus 500, having different transfer chamber 502 and loadlocks 504, described below. Whereas the example of FIG. 3 provides pre-cooling inside the transfer chamber, the pre-cooling may also occur outside of the transfer chamber. Items in FIG. 5 that are the same or similar to those in FIG. 3 are indicated by reference numerals having the same two least significant digits, with the most significant digit increased by 200. These items include: wafer 505, process cooling platen 506, scan motor 508, ion beam 510, process chamber 512, four loadport atmosphere transfer module 514, compressor-1 518, compressor-2 520, and temperature controller 540.

The wafer transfer chamber 502 need not include a cooling stage therein (but one may optionally be included). The loadlocks 504 are configured with a cooling stage 503 to pre-cool a semiconductor wafer 505 from a temperature at or above 15° C. to the desired implantation temperature between −270° C. and 5° C. The wafer transfer chamber 512 is coupled to the loadlock 504 to receive the pre-cooled wafer 505 from the loadlocks 504 without exposing the wafer to an ambient atmosphere. As in the case of FIG. 3, the process chamber 512 is configured to receive the pre-cooled wafer 505 from the wafer transfer chamber 502 and to perform an ion implantation step on the wafer at the temperature between −270° C. and 5° C.

U.S. Pat. No. 6,375,746 describes a water cooled loadlock for cooling a single wafer after a high-temperature process is performed in a reactor (process chamber), to reduce the temperature of a wafer for safe return to the wafer cassette, which would be damaged by a high temperature wafer. A similar cooling structure may be applied in the cooling stage 503 of the present loadlock 504 using an alternative coolant from the group consisting of liquid hydrogen, liquid helium, liquid nitrogen, liquid oxygen, liquid methane, and liquid nitrous oxide, to pre-cool the wafer prior to implantation. Alternatively, a batch cooling loadlock as described in U.S. Pat. No. 5,512,320 may be modified to include use of one of these cryogenic coolants. Accordingly, the teachings of U.S. Pat. Nos. 6,375,746 and 5,512,320 are incorporated by reference herein. Because the loadlocks in these patents are described for use in cooling wafers from processing temperatures (300° C. to 450° C.) to ambient temperature after processing, one of ordinary skill can readily make appropriate substitutions of materials and components suitable for use at subzero temperatures for the loadlock 504 of FIG. 5. Alternatively, other commercially available loadlocks with cooling capability may be used, with similar substitution of materials and components suitable for sub-zero temperatures.

A separate compressor may optionally be provided for the loadlocks 504 under common control by temperature controller 540, as shown in FIG. 5. This may provide greater flexibility, since the loadlocks 504 may be moved away form the port of the wafer transfer chamber 502. Alternatively, a coolant line may be added connecting the process cooling platen 506 and the loadlock(s) 504 to provide the coolant to the loadlocks 504. Alternatively, an additional parallel line may be added directly connecting the compressor-1 518 and the loadlocks 504.

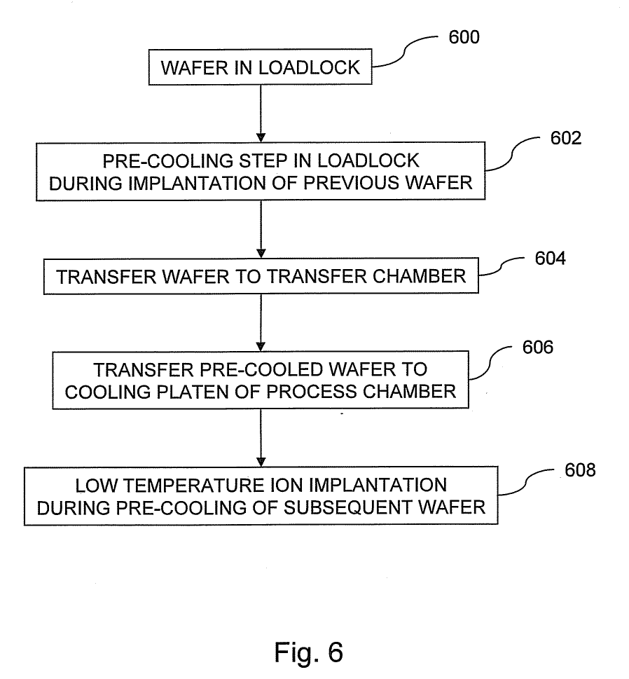

FIG. 6 is a flow chart of an exemplary method of using the apparatus of FIG. 5.

At step 600, the wafer 505 is placed in one of the loadlocks 504. The loadlock 504 is sealed and the atmosphere is vacuumed out of the loadlock.

At step 602, the wafer 305 is pre-cooled in the loadlock 504, outside of the process chamber 512. Preferably, the wafer 505 is pre-cooled to the temperature at which ion implantation is to occur. During the time that the pre-cooling step is performed, a previous wafer is either being transferred into position in the process chamber 512 or on the process cooling platen 506, being subjected to the ion implantation. Thus, two steps are being performed in parallel.

At step 604, the port between the loadlock 504 and wafer transfer chamber 502 is opened, and the wafer 505 is transferred to the wafer transfer chamber.

At step 606, the pre-cooled wafer 505 is transferred from the wafer transfer chamber 502 to the cooling platen 506 of the process chamber.

At step 608, the low temperature ion implantation step is performed while the next succeeding wafer is already being pre-cooled in the loadlock 502. Thus, the apparatus 500 is capable of starting the ion implantation step within a first period of time after the wafer 505 is placed on the process cooling platen 506, where the first period of time is shorter than a second period of time (e.g., 15-20 seconds) within which the process cooling platen 506 is capable of cooling a semiconductor wafer from the temperature at or above 15° C. to the temperature between −270° C. and 5° C. The duty cycle of the process chamber 512 is thus improved. Instead of waiting 15-20 seconds (while a wafer cools) between implantation steps, the only delay between implantation steps is the amount of time used to remove a first wafer 505 from the process cooling platen 506 of the process chamber 512 and to transfer a second wafer to the process cooling platen 506. This time interval is substantially less than the 15-20 second delay of pre-cooling the wafer 505, and may be only a few seconds.

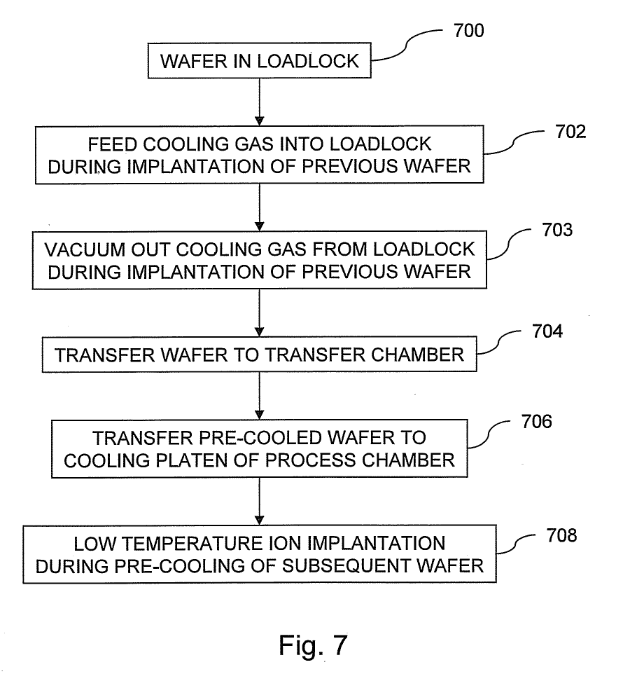

FIG. 7 is a flow chart of another exemplary method of using the apparatus of FIG. 5, or a similar apparatus having a gas cooled loadlock.

At step 700, the wafer 505 is placed in one of the loadlocks 504. The loadlock 504 is sealed.

At step 702, the wafer 305 is pre-cooled in the loadlock 504, outside of the process chamber 512. Preferably, the wafer 505 is pre-cooled to the temperature at which ion implantation is to occur. In the case of a gas cooled loadlock, a cooling gas is dispensed in the loadlock, which may be chilled air or a cryogenically chilled gas. Because the heat capacity of a gas is lower than that of a liquid, a cooling gas may be continuously pumped through the loadlock for a period of time instead of merely filling the loadlock with a volume of the gas and closing the loadlock.

At step 703, the loadlock 504 is sealed, and the cooling gas is vacuumed out.

During the time that the pre-cooling step is performed in steps 702 and 703, a previous wafer is either being transferred into position in the process chamber 512 or on the process cooling platen 506, being subjected to the ion implantation. Thus, two steps are being performed in parallel.

At step 704, the port between the loadlock 504 and wafer transfer chamber 502 is opened, and the wafer 505 is transferred to the wafer transfer chamber.

At step 706, the pre-cooled wafer 505 is transferred from the wafer transfer chamber 502 to the cooling platen 506 of the process chamber.

At step 708, the low temperature ion implantation step is performed while the next succeeding wafer is already being pre-cooled in the loadlock 502. This is the same as the step 608 described above.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method comprising the steps of:
(a) pre-cooling a first semiconductor wafer outside of a process chamber, from a temperature at or above 15° C. to a temperature below 5° C.;
(b) placing the pre-cooled first wafer inside the process chamber after step (a); and
(c) performing a low-temperature ion implantation on the first wafer after step (b).

2. The method of claim 1, wherein step (a) is performed while a second wafer is subjected to ion implantation in the process chamber.

3. The method of claim 2, further comprising:
removing the second wafer from a process cooling platen after the second wafer is subjected to the ion implantation; and
loading the first wafer onto the process cooling platen,
wherein a time interval between an end of step (b) and a beginning of step (c) is less than a duration of step (a).

4. The method of claim 1, wherein step (a) includes performing the pre-cooling step in a loadlock chamber.

5. The method of claim 4, wherein step (a) is performed before placing the first wafer in a wafer transfer chamber.

6. The method of claim 4, wherein step (a) includes:
positioning the first wafer inside the loadlock chamber;
feeding a cooling gas into the loadlock chamber to cool the first wafer; and
vacuuming out the cooling gas from the loadlock chamber.

7. The method of claim 1, wherein step (a) includes performing the pre-cooling step in a wafer transfer chamber near the process chamber.

8. The method of claim 7, wherein step (a) includes pre-cooling the first wafer on a cooling stage inside the wafer transfer chamber.

9. The method of claim 9, wherein step (a) includes pre-cooling the first wafer using a coolant at a temperature of −162° C. or lower.

10. The method of claim 1, wherein step (a) includes pre-cooling the first wafer using a coolant at a temperature of −196° C. or lower.

11. The method of claim 1, wherein step (a) includes pre-cooling the wafer using a coolant from the group consisting of liquid hydrogen, liquid helium, liquid nitrogen, liquid oxygen, liquid methane, and liquid nitrous oxide.

12. Apparatus comprising:
a loadlock configured to pre-cool a first semiconductor wafer from a first temperature to a second temperature, where the first temperature is at least 15° C., the second temperature is greater than or equal to −270° C., and the second temperature is less than or equal to 5° C.;
a wafer transfer chamber coupled to the loadlock to receive the pre-cooled wafer therefrom without exposing the wafer to an ambient atmosphere;
a process chamber configured to receive the pre-cooled wafer from the wafer transfer chamber and to perform an ion implantation step on the wafer at the temperature greater than or equal to −270° C. and less than or equal to 5° C.

13. The apparatus of claim 12, wherein a wafer stage of the loadlock is cooled using a coolant from the group consisting of liquid hydrogen, liquid helium, liquid nitrogen, liquid oxygen, liquid methane, and liquid nitrous oxide.

14. The apparatus of claim 12, wherein the process chamber has a process cooling platen, and the apparatus is capable of starting the ion implantation step within a first period of time after the wafer is placed on the process cooling platen, the first period of time being shorter than a second period of time within which the process cooling platen is capable of cooling a semiconductor wafer from the temperature at or above 15° C. to the temperature greater than or equal to −270° C. and less than or equal to 5° C.

15. The apparatus of claim 12, further comprising a temperature controller that controls both the temperature of the loadlock and a cooling platen that holds the wafer within the process chamber.

16. Apparatus comprising:
a wafer transfer chamber coupled to receive a semiconductor wafer from a loadlock and configured to pre-cool a first semiconductor wafer from a first temperature to a second temperature, where the first temperature is at least 15° C., the second temperature is greater than or equal to −270° C., and the second temperature is less than or equal to 5° C.;
a process chamber configured to receive the pre-cooled wafer from the wafer transfer chamber and to perform an ion implantation step on the wafer at the temperature greater than or equal to −270° C. and less than or equal to 5° C.

17. The apparatus of claim 16, wherein the wafer transfer chamber has a cooling stage inside the wafer transfer chamber.

18. The apparatus of claim 17, further comprising:
a common coolant source that provides a coolant to the cooling stage of the wafer transfer chamber and to a process cooling platen that holds and cools the wafer within the process chamber; and
a temperature controller that controls both the temperature of the cooling stage and the cooling platen.

19. The apparatus of claim 18, wherein the cooling stage and the cooling platen are cooled using a coolant from the group consisting of liquid hydrogen, liquid helium, liquid nitrogen, liquid oxygen, liquid methane, and liquid nitrous oxide.

20. The apparatus of claim 16, wherein the process chamber has a process cooling platen, and the apparatus is capable of starting the ion implantation step within a first period of time after the wafer is placed on the process cooling platen, the first period of time being shorter than a second period of time within which the process cooling platen is capable of cooling a semiconductor wafer from the temperature at or above 15° C. to the temperature greater than or equal to −270° C. and less than or equal to 5° C.
